(19) United States
(12) Patent Application Publication
(10) Pub. No.: US 2008/0044971 A1
(43) Pub. Date: Feb. 21, 2008

(54) METHOD FOR FABRICATING A SEMICONDUCTOR DEVICE HAVING A CAPACITOR

(75) Inventors: Dae-Hyuk KANG, Gyeonggi-do (KR); Chang-Ki HONG, Gyeonggi-do (KR); Kun-Tack LEE, Gyeonggi-do (KR); Im-Soo PARK, Seoul (KR); Dong-Gyun HAN, Gyeonggi-do (KR); Mong-Sup LEE, Gyeonggi-do (KR); Jung-Min OH, Incheon (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO,. LTD., Gyeonggi-do (KR)

(21) Appl. No.: 11/832,715

(22) Filed: Aug. 2, 2007

(30) Foreign Application Priority Data
Aug. 21, 2006 (KR) 10-2006-0078837

(51) Int. Cl. H01L 21/8242; H01L 21/44

(52) U.S. Cl. 438/253; 438/657; 257/E21.646; 257/E21.476

(57) ABSTRACT

A method for fabricating a semiconductor device is disclosed. The method includes forming an etch stop layer on a substrate, forming a mold layer on the substrate, and forming an opening exposing the substrate by patterning the mold layer and the etch stop layer, wherein the opening includes a lower portion defined by the etch stop layer and a middle portion. The method further includes enlarging the lower portion by etching a side portion of the etch stop layer exposed by the opening using an etching solution including sulfuric acid and water; and forming a lower electrode on an inner surface of the opening including the enlarged lower portion, wherein, after enlarging the lower portion, a width of the lower portion is greater than a width of the middle portion.

### CROSS-REFERENCE TO RELATED APPLICATION

This application claims priority to Korean Patent Application No. 2006-0078837, filed Aug. 21, 2006, the subject matter of which is hereby incorporated by reference in its entirety.

### BACKGROUND OF THE INVENTION

1. Field of the Invention

Embodiments of the invention relate to a method for fabricating a semiconductor device. In particular, embodiments of the invention relate to a method for fabricating a semiconductor device comprising a capacitor.

2. Description of the Related Art

In general, a semiconductor memory device such as a dynamic random access memory (DRAM) device can store data (e.g., program instructions, etc.), read the data stored in the device, and store new data provided to the device. Conventionally, a single memory cell comprises a transistor and a capacitor. A capacitor of a DRAM device comprises a storage electrode, a dielectric layer, a plate electrode, etc., and it is desirable to increase the capacitance of the capacitor in order to increase the capacitance per unit area of the memory device comprising the capacitor.

As the degree of integration of a DRAM device increases, the area in which a unit cell is formed in the DRAM device decreases. Thus, to maintain the capacitance of a capacitor of a unit cell, the capacitor has been changed from having a flat shape to having a box shape, a cylindrical shape, etc. However, to form a DRAM device comprising inner structures having fine line widths of less than about 0.11 nm, capacitors in the DRAM device must have relatively large aspect ratios. Accordingly, a 2-bit failure (i.e., a 2-bit fail) may occur between adjacent capacitors.

FIG. 1 is a cross-sectional view of a conventional capacitor having a cylindrical shape.

Referring to FIG. 1, the conventional capacitor having the cylindrical shape includes a storage electrode 13 having a cylindrical shape. Storage electrode 13 makes electric contact with a contact pad 4 formed in a semiconductor substrate 1. Storage electrode 13 makes electric contact with the contact pad 4 through a contact plug 10 extending through an insulating layer 7 formed on semiconductor substrate 1. In the capacitor illustrated in FIG. 1, a height of storage electrode 13 may be increased to enhance a cell capacitance of the semiconductor device in which it is included, such as a DRAM device. However, when the height of storage electrode 13 is increased too much, storage electrode 13 may lean, as illustrated by the dotted lines of FIG. 1. Thus, adjacent capacitors may become connected to one another and a 2-bit failure may occur between adjacent capacitors.

In addressing the problem described above, a semiconductor memory device having improved mechanical integrity, and a method for fabricating the semiconductor memory device, is disclosed in U.S. Patent Application Publication No. 2003/0085420. In accordance with U.S. Patent Application Publication No. 2003/0085420, the lower electrodes of adjacent capacitors are connected to one another by an insulating member having a beam shape.

FIG. 2 is a cross-sectional view illustrating a conventional semiconductor device disclosed in U.S. Patent Application Publication No. 2003/0085420. FIG. 3 is a plan view illustrating the conventional semiconductor device disclosed in U.S. Patent Application Publication No. 2003/0085420 and illustrated in FIG. 2.

Referring to FIGS. 2 and 3, an isolation layer 18 is formed on a surface of a semiconductor substrate 15 to divide semiconductor substrate 15 into an active region and a field region. Gate structures 27 each including a gate oxide layer pattern, a gate electrode, and a mask pattern are then formed on the active region.

Impurities are implanted into portions of semiconductor substrate 15 that are exposed between gate structures 27 through an ion implantation process using gate structures 27 as an ion implantation mask. Thus, source/drain regions 21 and 24 are formed at portions of semiconductor substrate 15 exposed between gate structures 27. Accordingly, metal-oxide-semiconductor (MOS) transistors may be formed on semiconductor substrate 15.

A first insulating interlayer 42 is formed on semiconductor substrate 15 on which the MOS transistors are formed. A capacitor plug 30 and a bit line plug 33 that respectively make contact with source/drain regions 21 and 24 are formed through first insulating interlayer 42.

A second insulating interlayer 45 is formed on first insulating interlayer 42. Thereafter, second insulating interlayer 45 is partially etched to form a hole through second insulating interlayer 45. A bit line contact plug 36 making contact with bit line plug 33 is formed in the hole. A third insulating interlayer is then formed on second insulating interlayer 42. Thereafter, third insulating interlayer 48 and second insulating interlayer 45 are sequentially etched to form a hole through third insulating interlayer 48 and second insulating interlayer 45. A capacitor contact plug 39 making contact with capacitor plug 30 is formed in the hole.

An etch stop layer 51 is formed on capacitor contact plug 39 and third insulating interlayer 48. Thereafter, a contact hole 54 exposing capacitor contact plug 39 is formed by partially etching etch stop layer 51. A lower electrode 57 having a cylindrical shape is formed such that lower electrode 57 makes contact with capacitor contact plug 39. Lower electrode 57 having the cylindrical shape makes electric contact with source/drain regions 21 through capacitor contact plug 39 and capacitor plug 30.

An insulating member 72 having a beam shape is formed between sidewalls of adjacent lower electrodes 57 so that the adjacent lower electrodes 57 are connected to one another by insulating member 72. A dielectric layer 60 and an upper electrode 63 are sequentially formed on lower electrode 57. Thus, a capacitor 66 is formed. An insulating layer 69 electrically insulating capacitor 66 from an upper wire is formed to cover capacitor 66. Here, the upper wire is formed after capacitor 66 is formed. Accordingly, lower electrodes 57 of capacitors 66 are connected to one another by insulating member 72 formed between the sidewalls of lower electrodes 57.

In the semiconductor device described above, the mechanical integrity of capacitor 66 is improved by insulating member 72 having the beam shape. However, because insulating members 72 are connected between sidewalls of adjacent lower electrodes 57, a process for fabricating capacitors 66 may be relatively complex. Furthermore, the cost and time required for fabricating the semiconductor memory device may relatively great.

As illustrated in FIGS. 2 and 3, the shape of capacitor 66 is relatively complex because dielectric layer 60 and upper electrode 63 are both formed on insulating member 72. Because capacitor 66 has a complex shape, processes for fabricating capacitor 66 are relatively difficult to perform. In addition, when insulating layer 69 electrically insulating capacitor 66 from the upper wire is formed to cover capacitor 66, insulating layer 69 may not fully cover an inner portion of capacitor 66. Furthermore, the complex shape of capacitor 66 may negatively impact (i.e., reduce) the yield of semiconductor devices comprising capacitor 66.

In addition, in accordance with Korean Patent Laid-Open Publication No. 2001-17022, an opening is formed by etching a mold oxide layer. Thereafter, a portion of an etch stop layer exposed through the opening is removed using a phosphoric acid solution to expose a pad conductive layer. Thus, a contact area between the pad conductive layer and a lower electrode of a subsequently formed capacitor may increase. However, when a portion of the etch stop layer is removed using the phosphoric acid solution, a portion of the mold oxide layer is also removed. Accordingly, a bridge causing an electric short between middle portions of the capacitors may be formed.

### SUMMARY OF THE INVENTION

Embodiments of the invention provide a method for fabricating a semiconductor device that aids in preventing the formation of a bridge between middle portions of capacitors. The formation of a bridge between capacitors may cause an electrical short.

In one embodiment, the invention provides a method for fabricating a semiconductor device. The method comprises forming an etch stop layer on a substrate, wherein the etch stop layer comprises a nitride; forming a mold layer on the substrate, wherein the mold layer comprises an oxide; and forming an opening exposing the substrate by patterning the mold layer and the etch stop layer, wherein the opening comprises a lower portion defined by the etch stop layer and a middle portion. The method further comprises enlarging the lower portion by etching a side portion of the etch stop layer exposed by the opening using an etching solution comprising sulfuric acid and water; and forming a lower electrode on an inner surface of the opening comprising the enlarged lower portion, wherein, after enlarging the lower portion, a width of the lower portion is greater than a width of the middle portion.

### BRIEF DESCRIPTION OF THE DRAWINGS

Embodiments of the invention will be described with reference to the accompanying drawings, in which:

FIG. 1 is a cross-sectional view of a conventional capacitor having a cylindrical shape;

FIG. 2 is a cross-sectional view of a conventional semiconductor device disclosed in U.S. Patent Application Publication No. 2003/0085420;

FIG. 3 is a plan view of the conventional semiconductor device disclosed in U.S. Patent Application Publication No. 2003/0085420 and illustrated in FIG. 2;

FIGS. 4 through 11 are cross-sectional views illustrating a portion of a method for fabricating a semiconductor device in accordance with an embodiment of the invention;

FIG. 12 is a graph showing, for each of several types of layers, the amount of the layer that was etched using a first etching solution and the amount that was etched using a second etching solution;

FIG. 13 is a scanning electron microscope (SEM) picture showing an initial opening formed by processes described with reference to FIGS. 8 and 9;

FIG. 14 is a SEM picture showing an enlarged opening formed by processes described with reference to FIGS. 10 and 11;

FIG. 15 is a SEM picture showing a conventional opening formed through a conventional method; and,

FIGS. 16 through 19 are cross-sectional views illustrating a method for fabricating a semiconductor device in accordance with an embodiment of the invention.

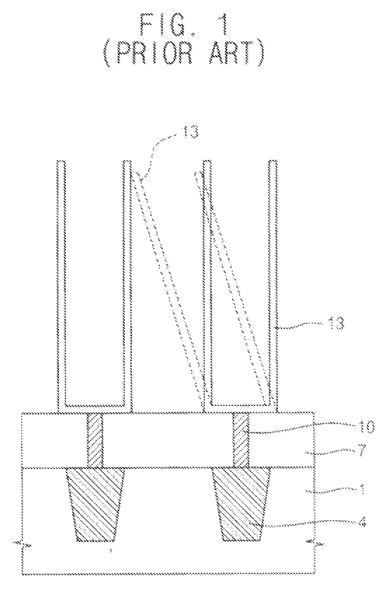

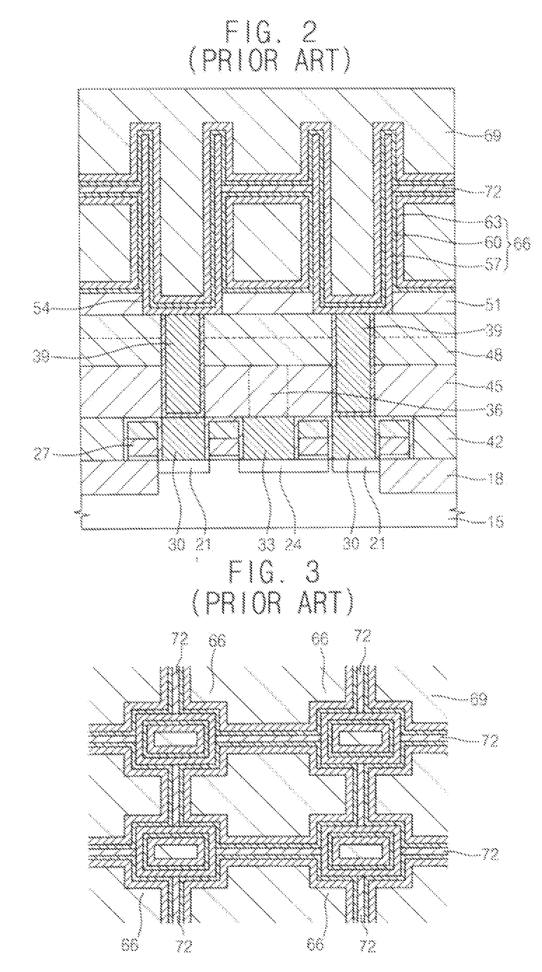

### DESCRIPTION OF EMBODIMENTS

When a first element or layer is referred to herein as being “on,” “connected to,” and/or “coupled to” a second element or layer, the first element or layer may be directly on, directly connected to, and/or directly coupled to the second element or layer, or intervening elements or layers may be present. In contrast, when a first element or layer is referred to as being “directly on,” “directly connected to,” and/or “directly coupled to” a second element or layer, no intervening elements or layers are present.

In addition, although terms such as “first,” “second,” etc., may be used herein to describe various elements, components, regions, layers, and/or sections, these elements, components, regions, layers, and/or sections are not limited by these terms. Rather, these terms are used merely for convenience of description to distinguish one element, component, region, layer, and/or section from another element, component, region, layer, and/or section. For example, a first element, component, region, layer, and/or section may be referred to as a second element, component, region, layer, and/or section without departing from the scope of the invention as defined by the accompanying claims.

Spatially relative terms, such as “beneath,” “below,” “lower,” “above,” “upper” and the like, may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, when the device in the figures is turned over, elements described as below and/or beneath other elements or features would then be oriented above the other elements or features. The device may be otherwise oriented (e.g., rotated 90 degrees) and the spatially relative descriptors used herein are to be interpreted accordingly.

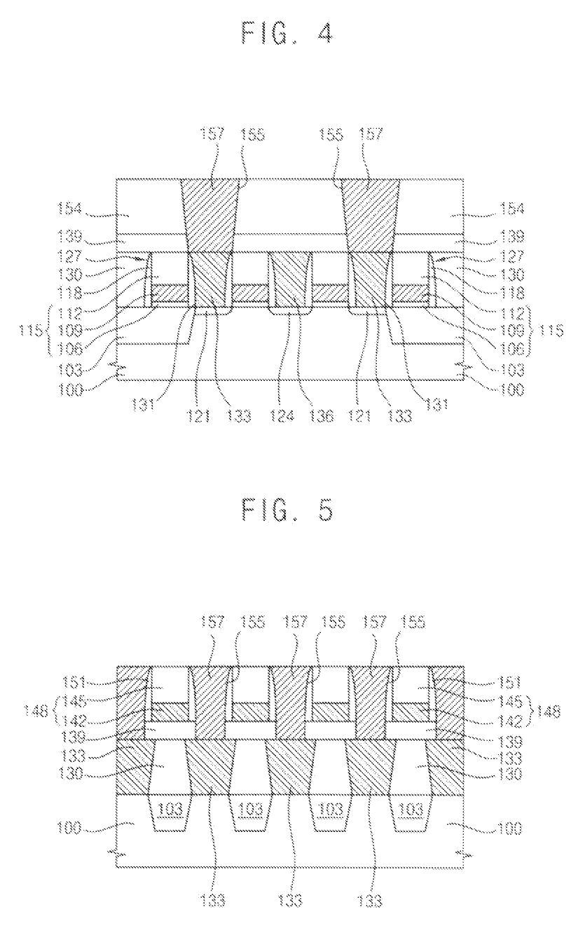

FIGS. 4 through 11 and 16 through 19 are cross-sectional views illustrating a method for fabricating a semiconductor device in accordance with an embodiment of the invention.

FIGS. 4 and 5 are cross-sectional views illustrating conductive structures disposed on a semiconductor substrate. FIG. 4 is a cross-sectional view taken along a bit line of the semiconductor device and FIG. 5 is a cross-sectional view taken along a word line of the semiconductor device. The formation of the conductive structures disposed on the semiconductor substrate will be described below with reference to FIGS. 4 and 5.

Referring to FIGS. 4 and 5, an isolation layer 103 is formed on a surface of a semiconductor substrate through an isolation process such as a shallow trench isolation (STI) process, a local oxidation of silicon (LOCOS) process, etc. Accordingly, substrate 100 is divided into an active region and a field region. Although the drawings may illustrate more than one of a particular element, in general, only one of each element will be described herein. However, more than one of a particular element may be described herein.

A relatively thin gate oxide layer (not shown) is formed on semiconductor substrate 100 through one of a thermal oxidation process, a chemical vapor deposition (CVD) process, etc. In accordance with an embodiment of the invention, the gate oxide layer may be formed only on the active region defined by isolation layer 103. A gate oxide pattern 106 may be formed subsequently by patterning the gate oxide layer.

A first conductive layer (not shown) and a first mask layer (not shown) are subsequently formed on the gate oxide layer. The first conductive layer corresponds to a gate conductive layer and the first mask layer corresponds to a gate mask layer. The first conductive layer may comprise polysilicon doped with impurities. The first conductive layer will subsequently be patterned into a gate conductive pattern 109. Alternatively, the first conductive layer may have a polycide structure comprising polysilicon doped with impurities and metal silicide. The gate mask layer will subsequently be patterned into a gate mask 112 (comprising gate mask patterns 112). The first mask layer may be formed from a material having an etching selectivity with respect to a first insulating interlayer 130 that will be formed subsequently. For example, when first insulating interlayer 130 comprises an oxide, the first mask layer may comprise a nitride such as silicon nitride.

A first photoresist pattern (not shown) is formed on the first mask layer. Thereafter, the first mask layer, the first conductive layer, and the gate oxide layer are successively etched using the first photoresist pattern as an etch mask to form gate structures (or word line structures) 115 on semiconductor substrate 100. Each gate structure 115 comprises a gate oxide pattern 106, a gate conductive pattern 109, and a gate mask pattern 112. The first mask layer, the first conductive layer, and the gate oxide layer may be sequentially patterned through an etching process using the first photoresist pattern as an etch mask, for example. Thus, gate structures 115 are formed on semiconductor substrate 100.

In accordance with another embodiment of the invention, the first mask layer is patterned using the first photoresist pattern as an etch mask to form a gate mask 112 (comprising gate mask patterns 112) on the first conductive layer. The first photoresist pattern formed on gate mask 112 is then removed. Then, the first conductive layer and the gate oxide layer are patterned using gate mask 112 as an etch mask to form gate structures 115 on semiconductor substrate 100, wherein each gate structure comprises a gate oxide pattern 106, a gate conductive pattern 109, and a gate mask pattern 112.

A first insulating layer (not shown) comprising a nitride such as silicon nitride is formed on semiconductor substrate 100 on which gate structures 115 are formed (i.e., the first insulating layer is formed on semiconductor substrate 100 after gate structures 115 are formed). Thereafter, the first insulating layer is anisotropically etched to form a first spacer 118 on a sidewall of a gate structure 115. First spacer 118 may be used as a gate spacer.

Impurities are implanted into portions of semiconductor substrate 100 exposed between gate structures 115 through an ion implantation process using gate structures 115 as ion implantation masks. Then, through a thermal treatment process, a first contact region 121 and a second contact region 124 are formed at the portions of semiconductor substrate 100 where the impurities were implanted. First contact region 121 and second contact region 124 may correspond to source/drain regions. Accordingly, metal-oxide-semiconductor (MOS) transistor structures 127 comprising first contact regions 121, second contact regions 124, and gate structures 115 are formed on semiconductor substrate 100. Each of first and second contact regions 121 and 124 may serve as a capacitor contact region or a bit line contact region. For example, a capacitor contact region makes contact with a first pad 133 for a capacitor and a bit line contact region makes contact with a second pad 136 for a bit line. Also, for example, a first contact region 121 of the source/drain regions may correspond to a capacitor contact region making contact with a first pad 133 and a second contact region 124 of the source/drain regions may correspond to a bit line contact region making contact with a second pad 136.

In accordance with another embodiment of the invention, impurities are lightly implanted into the portions of semiconductor substrate 100 exposed between gate structures 115 before first spacers 118 are formed on sidewalls of gate structures 115. First spacers 118 are then formed on sidewalls of gate structures 115. Thereafter, impurities are heavily implanted into portions of semiconductor substrate 100 disposed between gate structures 115. Thus, source/drain regions each having a lightly doped drain (LDD) structure are formed at the portions of semiconductor substrate 100 disposed between gate structures 115. First and second contact regions 121 and 124 may correspond to the source/drain regions.

Referring again to FIGS. 4 and 5, a first insulating interlayer 130 is formed on semiconductor substrate 100 to cover transistor structures 127. First insulating interlayer 130 comprises an oxide. The oxide may be boro-phosphor silicate glass (BPSG), phosphor silicate glass (PSG), tetra-ethyl-ortho-silicate (TEOS), undoped silicate glass (USG), spin-on-glass (SOG), high density plasma-chemical vapor deposition (HDP-CVD) oxide, etc.

First insulating interlayer 130 is planarized through a chemical mechanical polishing (CMP) process and/or an etch-back process until transistor structure 127 is exposed. Thus, an upper surface of first insulating interlayer 130 is planarized.

A second photoresist pattern (not shown) is formed on planarized first insulating interlayer 130. A portion of first insulating interlayer 130 is anisotropically etched using the second photoresist pattern as an etch mask so that first contact holes 131 may be formed through first insulating interlayer 130. First and second contact regions 121 and 124 may be exposed through first contact holes 131. When first insulating interlayer 130 comprising an oxide is etched, first insulating interlayer 130 may be etched using an etching gas having a high etching selectivity with respect to gate mask 112 comprising a nitride. Accordingly, first contact holes 131 may be aligned with respect to gate structures 115 to effectively expose first and second contact regions 121 and 124. For example, some first contact holes 131 expose first contact regions 121 corresponding to capacitor contact regions and other first contact holes 131 expose second contact regions 124 corresponding to bit line contact regions.

The second photoresist pattern is then removed. A second conductive layer (not shown) is formed on first insulating interlayer 130 to cover first contact holes 131 exposing first and second contact regions 121 and 124. The second conductive layer may comprise at least one of metal silicide, metal, and polysilicon that is heavily doped with impurities. The metal silicide may be titanium nitride. The metal may be tungsten, copper, etc.

The second conductive layer is planarized through a chemical mechanical polishing (CMP) process and/or an etch-back process until first insulating interlayer 130 is exposed to form first and second pads 133 and 136 on semiconductor substrate 100. First and second pads 133 and 136 may correspond to self-aligned contact (SAC) pads filling up first contact holes 131. A first pad 133, which corresponds to a first storage node contact pad, makes contact with a first contact region 121, which corresponds to a capacitor contact region. Second pad 136, which corresponds to a first bit line contact pad, makes contact with second contact region 124, which corresponds to a bit line contact region.

A second insulating interlayer 139 is formed on first insulating interlayer 130, in which first and second pads 133 and 136 are disposed. Second insulating interlayer 139 may electrically insulate first pad 133 from a bit line 148 that is formed subsequently. Second insulating interlayer 139 is formed using an oxide such as BPSG, PSG, USG, SOG, TEOS, HDP-CVD oxide, etc. First and second insulating interlayers 130 and 139 may be formed using the same oxide, for example. Alternatively, first and second insulating interlayers 130 and 139 may be formed using different oxides. Second insulating interlayer 139 may be planarized through a chemical mechanical polishing (CMP) process and/or an etch-back process to planarize an upper surface of second insulating interlayer 139.

A third photoresist pattern (not shown) is formed on second insulating interlayer 139. Second insulating interlayer 139 is partially etched using the third photoresist pattern as an etch mask so that a second contact hole (not shown) is formed through second insulating interlayer 139. Second pad 136 formed through first insulating interlayer 130 may be exposed through the second contact hole. The second contact hole may correspond to a bit line contact hole connecting second pad 136 to bit line 148, which is formed subsequently. In addition, a first anti-reflective layer (ARL) may be formed between second insulating interlayer 139 and the third photoresist pattern and may be formed from silicon oxide, silicon nitride, silicon oxynitride, etc. The second contact hole may then be formed through a photolithography process.

Referring again to FIGS. 4 and 5, the third photoresist pattern is removed. Thereafter, a third conductive layer (not shown) and a second mask layer (not shown) are sequentially formed on second insulating interlayer 139 to fill up the second contact hole. The third conductive layer and the second mask layer will subsequently be patterned into a bit line conductive pattern 142 and a bit line mask pattern 145, respectively.

A fourth photoresist pattern (not shown) is formed on the second mask layer. Thereafter, the second mask layer and the third conductive layer are sequentially patterned using the fourth photoresist pattern as an etch mask. Accordingly, a third pad (not shown) and bit line 148 may simultaneously be formed. The third pad may fill up the second contact hole. Bit line 148 may comprise bit line conductive pattern 142 and bit line mask pattern 145 that are formed on second insulating interlayer 139. The third pad may correspond to a second bit line contact pad electrically connecting second pad 136 to bit line 148.

Bit line conductive pattern 142 may comprise a first layer comprising a metal compound and a second layer comprising a metal. For example, the first layer may comprise a titanium film and a titanium nitride film formed on the titanium film. The second layer may comprise tungsten. Bit line mask pattern 145 may protect bit line conductive pattern 142 during a subsequent etching process that is performed to form a lower electrode. Bit line mask pattern 145 may comprise silicon nitride.

In accordance with another embodiment of the invention, the second mask layer is patterned using the fourth photoresist pattern as an etch mask to form a bit line mask 145 (comprising bit line mask patterns 145) on the third conductive layer. The fourth photoresist pattern is then removed. Thereafter, the third conductive layer is etched using bit line mask 145 as an etch mask to form bit line conductive pattern 142 on second insulating interlayer 139. The third pad electrically connecting second pad 136 to bit line conductive pattern 142 may be formed at the same time as the bit line conductive pattern 142 such that the third pad fills up the second contact hole formed through second insulating interlayer 139.

In accordance with still another embodiment of the invention, an additional conductive layer is formed to fill the second contact hole formed through second insulating interlayer 139. Thereafter, the third pad making contact with second pad 136 may be formed by planarizing the additional conductive layer until second insulating interlayer 139 is exposed. The third conductive layer and the second mask layer are then formed on second insulating interlayer 139, wherein the second contact hole is formed in second insulating interlayer 139, and wherein the third pad is formed in the second contact hole. The third conductive layer and the second mask layer are patterned to form bit line 148. Particularly, a barrier metal layer comprising a titanium film and a titanium nitride film, and a metal layer comprising tungsten are sequentially formed on second insulating interlayer 139 to thereby fill up the second contact hole exposing the third pad. Thereafter, the barrier metal layer and the metal layer are planarized through a CMP process and/or an etch-back process until second insulating interlayer 139 is exposed to form the third pad filling up the second contact hole. Second pad 136, the second contact hole, and the third pad may correspond to a bit line contact hole pad, a bit line contact hole, and a bit line contact plug, respectively. The third pad may make contact with second pad 136. The third conductive layer comprising a metal such as tungsten and the second mask layer are then formed on the third pad. Thereafter, the third conductive layer and the second mask layer are patterned to form bit line 148 comprising bit line conductive pattern 142 and bit line mask pattern 145. Bit line conductive pattern 142 may comprise, for example, one metal layer.

Referring again to FIGS. 4 and 5, a second insulating layer (not shown) is formed on bit lines 148 and the second insulating interlayer 139. The second insulating layer is anisotropically etched so that a second spacer 151 corresponding to a bit line spacer is formed on a sidewall of bit line 148. Second spacer 151 may be formed from a material having an etching selectivity with respect to second insulating interlayer 139 and a third insulating interlayer that is formed subsequently such that second spacer 151 may protect bit line 148 while a fourth pad 157 corresponding to a second storage node contact pad is formed. Here, second insulating interlayer 139 and third insulating interlayer may comprise an oxide. Second spacer 151 may comprise a nitride such as silicon nitride.

Third insulating interlayer 154 may be formed on second insulating interlayer 139 to cover bit line 148 having the sidewall on which second spacer 151 is formed. Third insulating interlayer 154 may comprise BPSG, PSG, USG, SOG, TEOS, HDP-CVD oxide, etc. As described above, second and third insulating interlayers 139 and 154 may be formed from the same oxide. Alternatively, second and third insulating interlayers 139 and 154 may be formed from different oxides. Third insulating interlayer 154 may be formed from HDP-CVD oxide capable of efficiently filling a gap between bit lines 148 at a relatively low temperature, and without generating a void.

Third insulating interlayer 154 may be polished through a chemical mechanical polishing (CMP) process and/or an etch-back process until bit line mask 145 is exposed in order to planarize an upper surface of third insulating interlayer 154. In accordance with another embodiment of the invention, a planarization process performed on third insulating interlayer 154 may be stopped before bit line mask 145 is exposed. Thus, a portion of third insulating interlayer 154 having a predetermined thickness may remain on bit line 148. In accordance with yet another embodiment of the invention, to prevent a void from forming in a portion of third insulating interlayer 154 disposed between adjacent bit lines 148, an additional insulating layer comprising a nitride is formed with a thickness of about 50 Å to 200 Å on bit line 148 and second insulating interlayer 139. Third insulating interlayer 154 may then be formed on the additional insulating layer.

A fifth photoresist pattern (not shown) is formed on planarized third insulating interlayer 154. Thereafter, third insulating interlayer 154 and second insulating interlayer 139 may be partially etched using the fifth photoresist pattern as an etch mask to form third contact holes 155 exposing first pads 133. Third contact holes 155 may correspond to storage node contact holes. For example, third contact holes 155 may be aligned with respect to second spacers 151 formed on sidewalls of bit lines 148. In accordance with another embodiment of the invention, a second anti-reflective layer (ARL) is additionally formed on third insulating interlayer 154 to increase a margin of a photolithography process that may be performed subsequently. The photolithography process may then be performed. In accordance with still another embodiment of the invention, a native oxide, a polymer, or a byproduct may be removed from a surface of first pads 133 exposed through third contact holes 155 through an additional cleaning process performed after third contact holes 155 are formed.

A fourth conductive layer is formed on third insulating interlayer 154 to cover third contact holes 155. The fourth conductive layer may be planarized through a CMP process and/or an etch-back process until third insulating interlayer 154 and bit lines 148 are exposed. Thus, fourth pads 157 may be formed in third contact holes 155. A fourth pad 157 may correspond to a second storage node contact pad and may be referred to herein as a “contact pad”. Fourth pad 157 may comprise polysilicon doped with impurities, metal, etc. A fourth pad 157 may electrically connect a first pad 133 to a storage electrode that will be formed subsequently. Accordingly, the storage electrode may be electrically connected to first contact region 121 through a fourth pad 157 and a first pad 133.

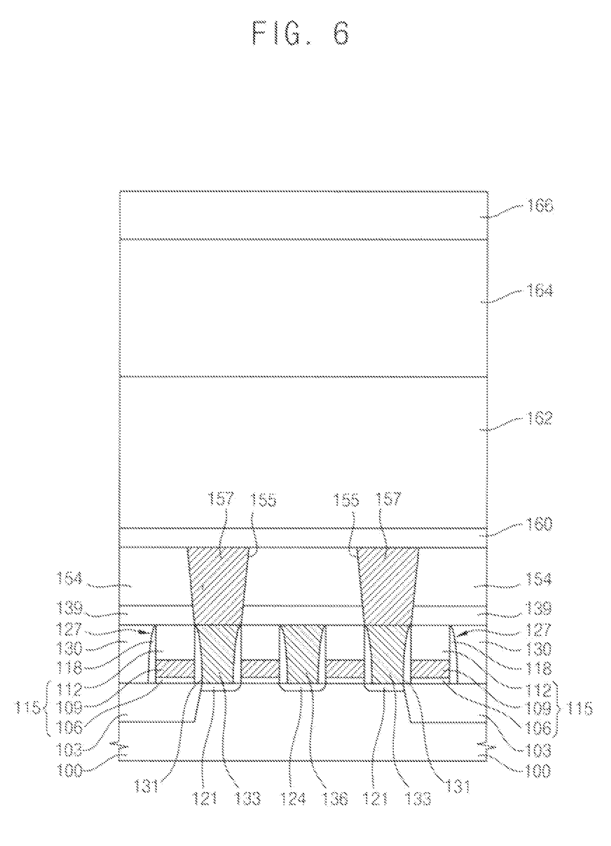

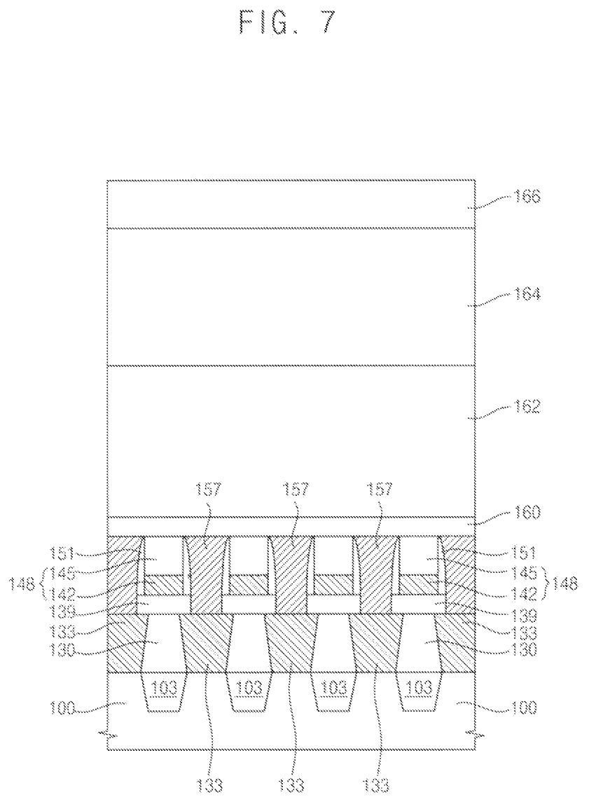

FIGS. 6 and 7 are cross-sectional views illustrating steps of forming mold layers on a conductive structure (i.e., a semiconductor structure) illustrated in FIGS. 4 and 5.

Referring to FIGS. 6 and 7, an etch stop layer 160, a first mold layer 162, and a second mold layer 164 are sequentially formed on fourth pad 157, bit line 148, and third insulating interlayer 154. First and second mold layers 162 and 164 may comprise silicon oxide, for example. Alternatively, second mold layer 164 may each comprise a material having an etching selectivity with respect to first mold layer 162. For example, first mold layer 162 may comprise BPSG and second mold layer 164 may comprise TEOS. Etch stop layer 160 may comprise a material having an etching selectivity with respect to first and second mold layers 162 and 164. Particularly, etch stop layer 160 may comprise silicon nitride.

In accordance with another embodiment of the invention, a fourth insulating interlayer is formed on fourth pad 157, bit line 148, and third insulating interlayer 154. An etch stop layer may then be formed on the fourth insulating interlayer.

Referring again to FIGS. 6 and 7, a third mask layer 166 is formed on second mold layer 164. Third mask layer 166 may comprise a material having an etching selectivity with respect to first and second mold layers 162 and 164. In addition, third mask layer 166 may be thicker than etch stop layer 160. Also, third mask layer 166 may comprise silicon nitride, for example.

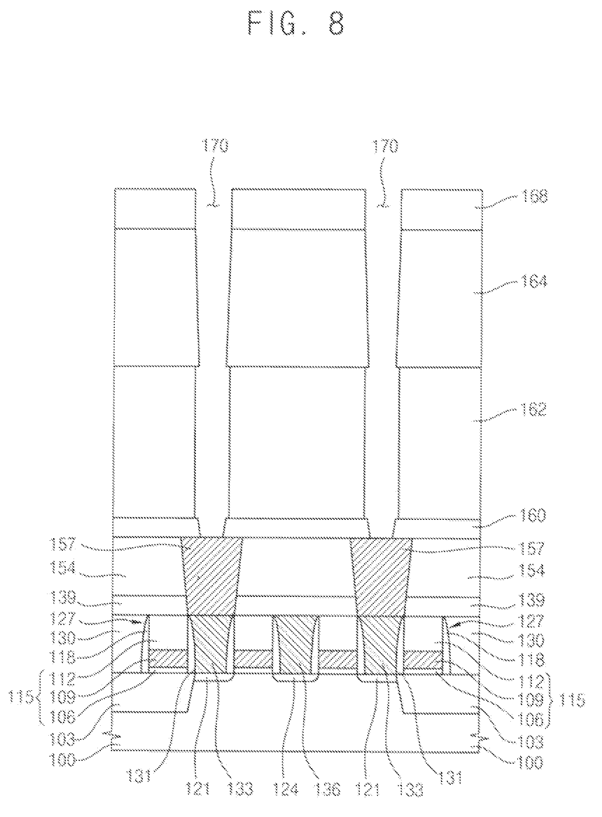

FIGS. 8 to 11 are cross-sectional views illustrating openings formed through first and second mold layers 162 and 164.

Referring to FIGS. 6 through 9, a photoresist pattern is formed on third mask layer 166. Third mask layer 166 is etched using the photoresist pattern as an etch mask so that third mask layer 166 may be transformed into a mask 168. The photoresist pattern may be removed through an ashing process and/or a stripping process after mask 168 is formed on second mold layer 164.

Second mold layer 164, first mold layer 162, and etch stop layer 160 are anisotropically etched using mask 168 as an etch mask after the photoresist pattern is removed. Thus, an opening 170 is formed. Opening 170 may be used to form a lower electrode having a cylindrical shape. To form opening 170, an etching process using mask 168 as an etch mask may initially be performed until etch stop layer 160 is exposed. The etching process may then be performed until a fourth pad 157 is exposed. That is, etch stop layer 160 may then be etched until fourth pad 157 is exposed. Mask 168 may be partially etched while etching etch stop layer 160.

Opening 170 comprises a lower portion defined by etch stop layer 160 and a middle portion defined by first mold layer 162. Etch stop layer 160 has an etching selectivity with respect to first and second mold layers 162 and 164. Thus, the lower portion of opening 170 may be narrower than the middle portion of opening 170.

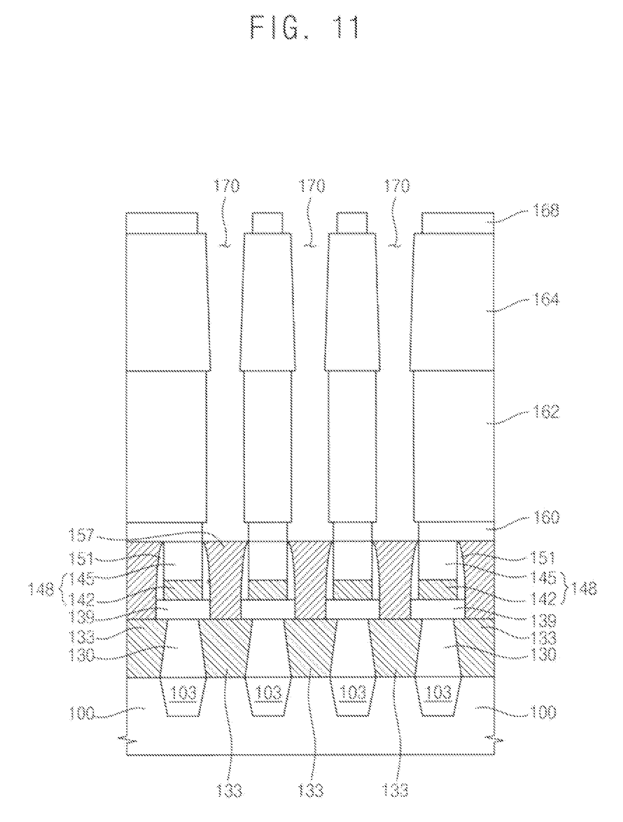

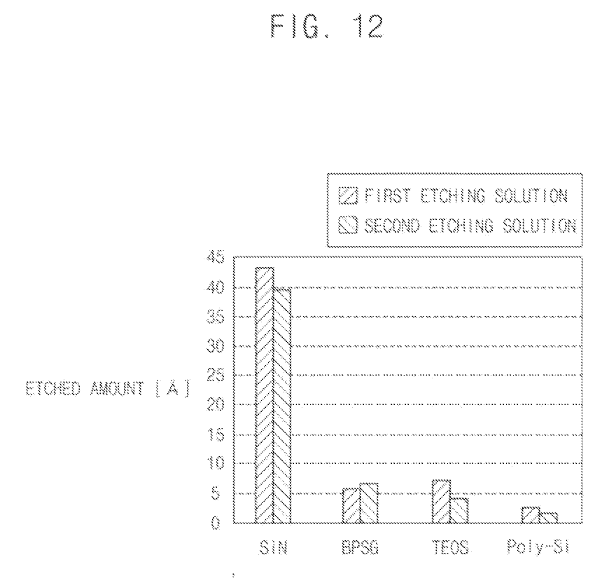

Referring to FIGS. 10 and 11, etch stop layer 160 is selectively etched to enlarge the lower portion of opening 170. For example, an etch rate of etch stop layer 160 may be greater than the respective etch rates of first and second mold layers 162 and 164 in an etching solution comprising sulfuric acid (H₂SO₄) and water (H₂O). In particular, an etching selectivity of silicon nitride with respect to BPSG in the etching solution comprising sulfuric acid and water may be no less than about 6. Mask 168 may be partially etched while etch stop layer 160 is etched. However, a portion of mask 168 may remain on etch stop layer 160 because mask 168 is thicker than etch stop layer 160.

A side portion of etch stop layer 160 exposed by opening 170 is selectively etched using the etching solution comprising sulfuric acid and water. Thus, the lower portion of opening 170 defined by etch stop layer 160 may be enlarged such that the lower portion of opening 170 is wider than the middle portion of opening 170 defined by first mold layer 162. Thus, the structural stability of a lower electrode that is subsequently conformably formed in opening 170 (i.e., enlarged opening 170) may be improved.

In addition, the etching solution may have a volume ratio of water to sulfuric acid of about 0.3 to about 0.7. In addition, the etch rate of etch stop layer 160 in the etching solution may be proportional to a temperature of the etching solution. Thus, the etching solution may be heated to increase the etch rate of etch stop layer 160 in the etching solution. For example, the etching solution may be heated to a temperature of about 100° C. to 160° C. As used herein, a “volume ratio” of a first substance to a second substance is the ratio of the volume of the first substance to the volume of the second substance.

In particular, semiconductor substrate 100 (on which etch stop layer 160, first mold layer 162, second mold layer 164, and mask 168 are formed) is placed in (i.e., dipped into) the etching solution by placing semiconductor substrate 100 in a container containing the etching solution. In addition, the container is sealed after semiconductor substrate 100 is placed in the container. After the container is sealed, the container may then be heated in order to increase the temperature of the etching solution.

The boiling point of the etching solution may be increased because the container is heated after the container is sealed. Thus, the etch rate of the etch stop layer 160 in the etching solution may be increased by heating the etching solution.

After the etching process using the etching solution is completed, the container may lose heat (i.e., cool). Thus, the temperature of the etching solution may decrease. Semiconductor substrate 100 is removed from the container.

In accordance with an embodiment of the invention, an inactive gas such as a nitrogen gas may be provided into the container, and the pressure inside the container may increase to about 2 atm. When the gas is provided into the container, the pressure inside of the container is controlled so that the container does not explode.

In accordance with another embodiment of the invention, when fourth pad 157 comprises polysilicon doped with impurities, the etching solution may further comprise hydrogen peroxide (H₂O₂). When the etching solution comprises hydrogen peroxide, the etching solution may have a volume ratio of hydrogen peroxide to sulfuric acid of about 0.01 to 0.2. The hydrogen peroxide may prevent a surface of fourth pad 157 from being etched during the etching process.

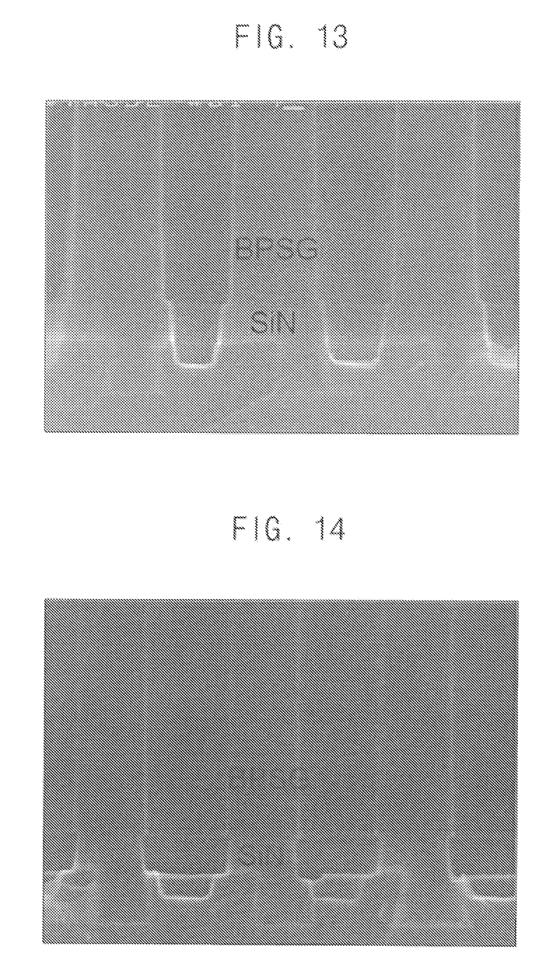

FIG. 12 is a graph showing, for each of several types of layers, the amount of the layer that was etched using a first etching solution and the amount that was etched using a second etching solution. The first etching solution comprises sulfuric acid and water, and the second etching solution comprises sulfuric acid, water, and hydrogen peroxide.

Silicon nitride layers, silicon oxide layers comprising BPSG, silicon oxide layers comprising TEOS, and polysilicon layers doped with N-typed impurities were each formed on semiconductor substrates. A first etching solution comprising about 25 liters of sulfuric acid and about 15 liters of water was prepared. In addition, a second etching solution comprising about 24 liters of sulfuric acid, about 25 liters of water, and about 4 liters of hydrogen peroxide was prepared. Etching processes were performed using each of the first and second etching solutions. Results of the etching processes are shown in FIG. 12. The etching processes were each performed for about 10 minutes with the etching solution having a temperature of about 135° C.

As shown in FIG. 12, the silicon nitride layer was etched much more than the silicon oxide layers and the polysilicon layer in both the first and second etching solutions. In addition, the polysilicon layer was etched less by the second etching solution than by the first etching solution.

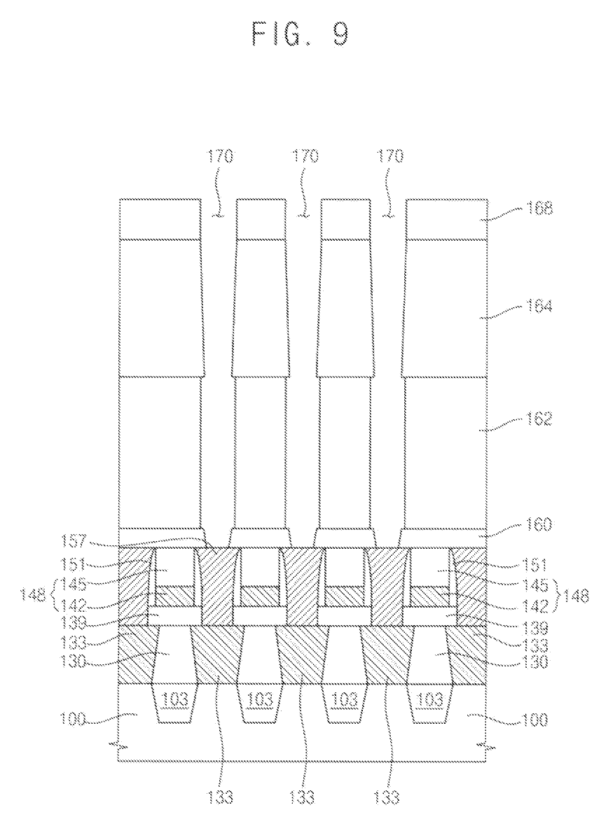

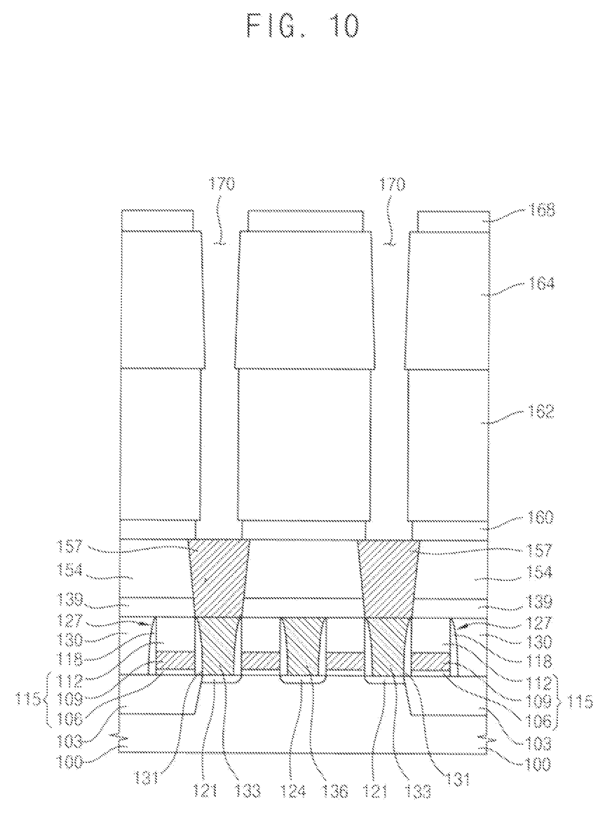

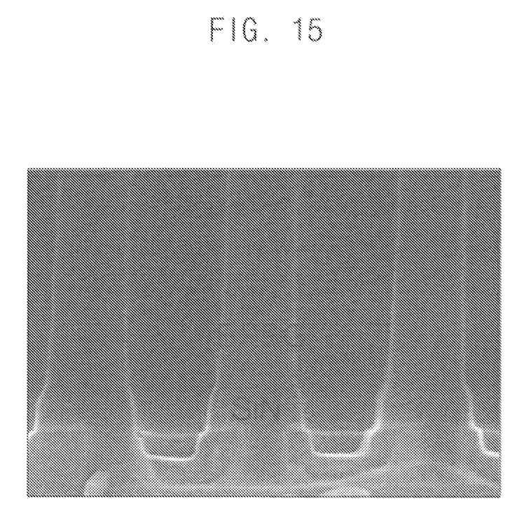

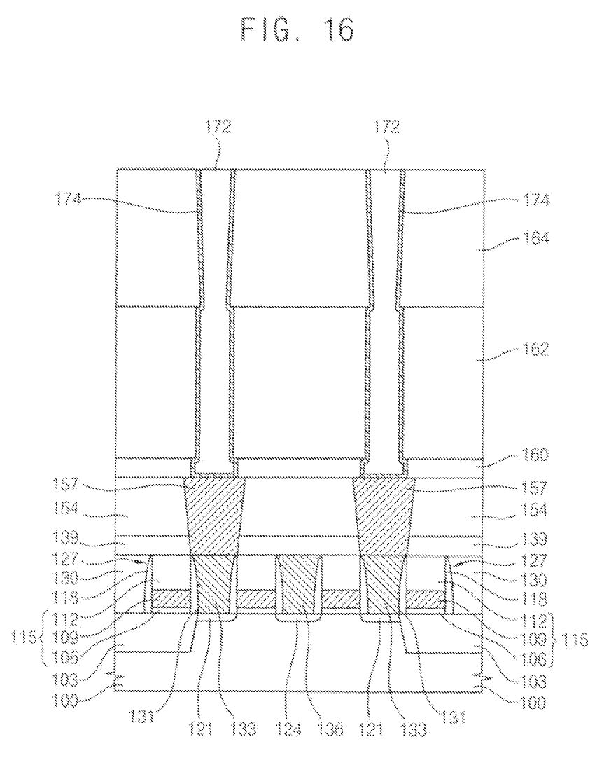

FIG. 13 is a scanning electron microscope (SEM) picture showing an initial opening formed through processes described with reference to FIGS. 8 and 9. FIG. 14 is a SEM picture showing an enlarged opening formed through processes described with reference to FIGS. 10 and 11. FIG. 15 is a SEM picture showing a conventional opening formed through a conventional method.

An isotropic etching process was performed on an etch stop layer and a mold layer comprising initial openings using an etching solution comprising about 25 liters of sulfuric acid and about 15 liters of water. The isotropic etching process was performed for about 20 minutes with the etching solution having a temperature of about 145° C. As a result, enlarged openings were formed through the etching process, as shown in FIG. 14.

As shown in FIG. 13, a mold layer and an etch stop layer were anisotropically etched to form an initial opening through the mold layer and the etch stop layer. A lower portion of the initial opening was narrower than a middle portion of the initial opening. However, as shown in FIG. 14, the initial opening was widened into an enlarged opening by performing the isotropic etching process using the etching solution on the mold layer and etch stop layer comprising the initial opening. As shown in FIG. 14, a lower portion of the enlarged opening is wider than a middle portion of the enlarged opening.

According to a conventional method, an etching process was performed using an etching solution including phosphoric acid for about 2 minutes at a temperature of about 155° C. As a result, a conventional opening was formed by the etching process, as shown in FIG. 15.

In the etching process according to the conventional method, the first mold layer and the etch stop layer had substantially the same etch rate in the etching solution including phosphoric acid. Thus, lower and middle portions of the conventional openings expanded in such a way that the reliability of a device comprising lower electrodes conformably formed in conventional openings may be inferior to that of a device comprising lower electrodes formed in accordance with an embodiment of the invention. For example, when the middle portions of the conventional openings expand, a distance between middle portions of adjacent lower electrodes formed in the conventional openings may decrease. Thus, a bridge, which may cause an electric short, may be formed between the middle portions of adjacent lower electrodes.

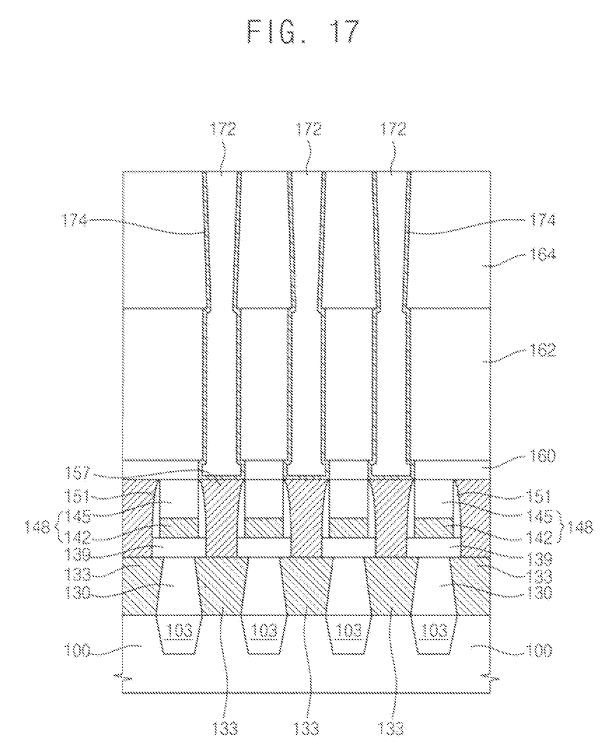

FIGS. 16 and 17 are cross-sectional views illustrating a lower electrode 174 conformably formed in enlarged opening 170.

Referring to FIGS. 10, 11, 16, and 17, a fifth conductive layer having a relatively uniform thickness is formed on mask 168 and an inner surface (i.e., an inner face) of opening 170. The fifth conductive layer may comprise titanium nitride. The fifth conductive layer may be formed through an atom layer deposition (ALD) process, a chemical vapor deposition (CVD) process, a physical vapor deposition (PVD) process, etc.

Thereafter, a sacrificial layer 172 may be formed on the fifth conductive layer to fill up opening 170. Sacrificial layer 172 may comprise silicon oxide. Sacrificial layer 172 may be formed through a CVD process.

After sacrificial layer 172 is formed, sacrificial layer 172 and the fifth conductive layer are planarized. Thus, lower electrode 174 is formed on the inner surface of opening 170. The fifth conductive layer and mask 168 may be planarized through a CMP process. The CMP process is performed until mask 168 is exposed. Mask 168 may serve as a polish stop layer when the CMP process is performed. Alternatively, the CMP process may be completed after mask 168 is removed.

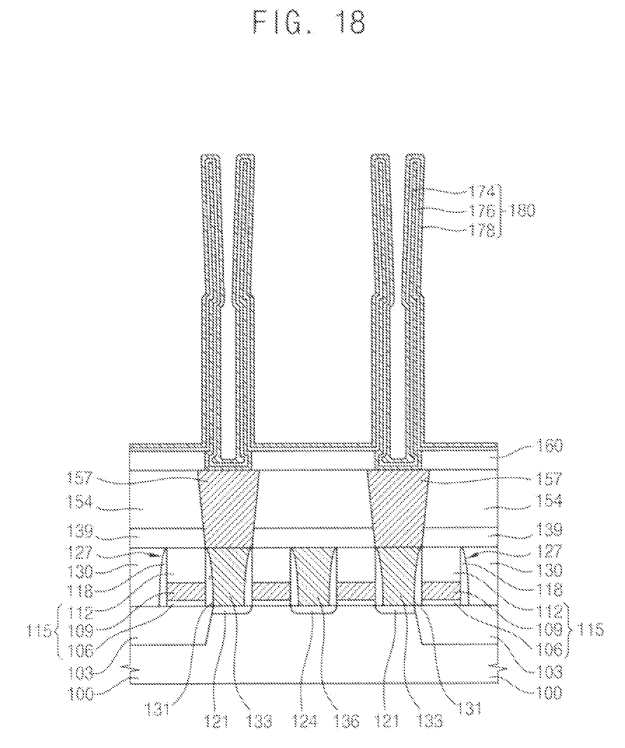

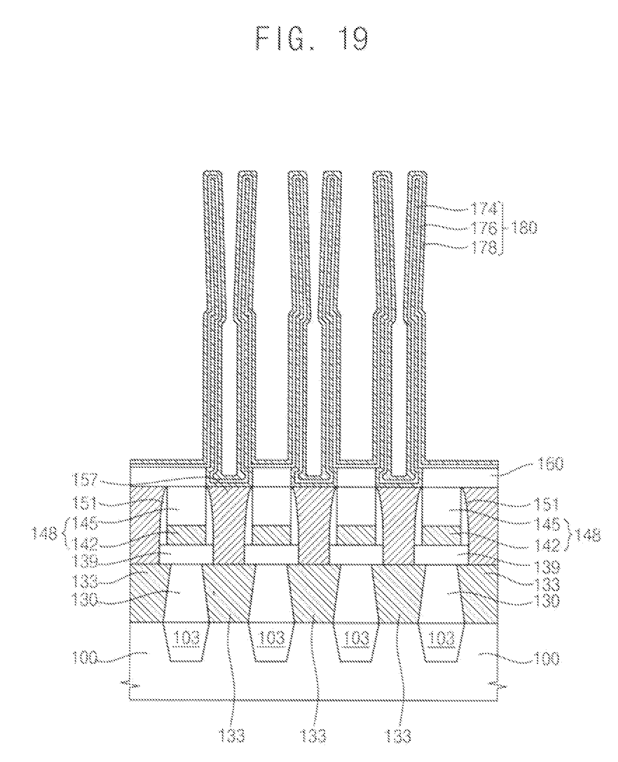

FIGS. 18 and 19 are cross-sectional views illustrating a capacitor 180 formed on semiconductor substrate 100.

Referring to FIGS. 16 through 19, second mold layer 164 and first mold layer 162 are removed through an isotropic etching process. The isotropic etching process may be a wet etching process using an etching solution, or a dry etching process using an etching gas. The isotropic etching process may be performed until etch stop layer 160 is exposed, for example. The etching solution may be, for example, an etching solution comprising hydrogen fluoride; an etching solution comprising ammonium hydroxide, hydrogen peroxide, and deionized (DI) water; a limulus amebocyte lysate (LAL) etching solution comprising ammonium fluoride, hydrogen fluoride, and water; an etching solution comprising phosphoric acid; etc. Also, the etching gas may be, for example, an etching gas comprising hydrogen fluoride and water vapor; an etching gas comprising carbon tetra-fluoride and oxygen; etc.

Referring to FIGS. 18 and 19, a dielectric layer 176 and an upper electrode 178 are subsequently formed on lower electrode 174 to form a capacitor 180. Dielectric layer 176 may comprise a silicon oxide, a silicon nitride, a material having a high dielectric constant, etc. The material having the high dielectric constant may be hafnium oxide (HfO₂), hafnium aluminum oxide (HfAlO), hafnium silicon oxynitride (HfSiₓO_{y}N_{z}), zirconium oxide (ZrO₂), zirconium silicon oxide (ZrSiₓO_{y}), zirconium silicon oxynitride (ZrSiₓO_{y}N_{z}), aluminum oxide (Al₂O₃), titanium oxide (TiO₂), yttrium oxide (Y₂O₃), tantalum oxide (Ta₂O₅), niobium oxide (Nb₂O₅), barium titanium oxide (BaTiO₃), strontium titanium oxide (SrTiO₃), etc. The upper electrode may comprise titanium nitride.

In accordance with embodiments of the invention, first and second mold layers and an etch stop layer are patterned to form an opening. Thereafter, a side portion of the etch stop layer is partially removed. Accordingly, a lower portion of the opening (which is defined by the etch stop layer) may become wider than a middle portion of the opening. A lower electrode is then formed on an inner surface of the opening, and, because the opening has a relatively wide lower portion, the structural stability of the lower electrode may be improved. For example, the lower electrode may not lean as readily as a conventional lower electrode, which may aid in preventing the occurrence of 2-bit failures. Forming capacitors using a method in accordance with an embodiment of the invention may aid in preventing 2-bit failure from occurring at adjacent capacitors, each of which comprises a lower electrode, a dielectric layer, and an upper electrode.

In addition, the middle portion of the opening may be narrower than the lower portion of the opening, so a lower portion of a lower electrode may be relatively wide while a distance between middle portions of adjacent lower electrodes may be relatively large. Forming lower electrodes such that there is a relatively large distance between the middle portions of adjacent lower electrodes may aid in preventing the formation of a bridge (which may cause an electrical short) between adjacent lower electrodes. Forming capacitors using a method in accordance with an embodiment of the invention may aid in preventing an electrical short from forming between adjacent capacitors.

Although embodiments of the invention have been described herein, modifications may be made to those embodiments by those skilled in the art without departing from the scope of the invention, as defined by the accompanying claims.

What is claimed is:

1. A method for fabricating a semiconductor device, the method comprising:
forming an etch stop layer on a substrate, wherein the etch stop layer comprises a nitride;
forming a mold layer on the substrate, wherein the mold layer comprises an oxide;
forming an opening exposing the substrate by patterning the mold layer and the etch stop layer, wherein the opening comprises a lower portion defined by the etch stop layer and a middle portion;
enlarging the lower portion by etching a side portion of the etch stop layer exposed by the opening using an etching solution comprising sulfuric acid and water; and,
forming a lower electrode on an inner surface of the opening comprising the enlarged lower portion,
wherein, after enlarging the lower portion, a width of the lower portion is greater than a width of the middle portion.

2. The method of claim 1, wherein the etching solution has a volume ratio of water to sulfuric acid of about 0.3 to 0.7.

3. The method of claim 1, wherein the etching solution has a temperature of about 100° C. to 160° C. when enlarging the lower portion.

4. The method of claim 1, wherein enlarging the lower portion comprises:
placing the substrate in the etching solution by providing the substrate into a container containing the etching solution;
sealing the container; and,
increasing the temperature of the etching solution by heating the sealed container.

5. The method of claim 4, wherein increasing the temperature of the etching solution comprises increasing the temperature of the etching solution to about 100° C. to 160° C.

6. The method of claim 4, further comprising, after enlarging the lower portion of the opening, reducing the temperature of the etching solution by cooling the container.

7. The method of claim 4, further comprising providing an inert gas into the sealed container.

8. The method of claim 1, wherein the mold layer comprises a first mold layer comprising boro-phosphor silicate glass and a second mold layer comprising tetra-ethyl-ortho-silicate.

9. The method of claim 1, further comprising forming a transistor on the substrate, wherein the opening exposes a contact pad electrically connected to the transistor.

10. The method of claim 9, wherein the contact pad comprises polysilicon.

11. The method of claim 10, wherein the etching solution further comprises hydrogen peroxide.

12. The method of claim 11, wherein the etching solution has a volume ratio of hydrogen peroxide to sulfuric acid of about 0.01 to 0.2.

13. The method of claim 1, further comprising:
forming a dielectric layer on the lower electrode; and
forming an upper electrode on the dielectric layer.

14. The method of claim 13, wherein the upper and lower electrodes each comprise titanium nitride.
